(19) United States
(12) Patent Application Publication
(10) Pub. No.: US 2008/0283089 A1
(43) Pub. Date: Nov. 20, 2008

(54) CLEANING APPARATUS OF SEMICONDUCTOR DEVICE

(76) Inventors: Sang-Wook Ryu, Cheongju-si (KR); Jim-Ho Park, Yeongju-si (KR)

Correspondence Address: SHERR & VAUGHN, PLLC, 620 HERNDON PARKWAY, SUITE 200, HERNDON, VA, 20170, US

(21) Appl. No.: 12/120,893

(22) Filed: May 15, 2008

(30) Foreign Application Priority Data
May 16, 2007 (KR) 10-2007-0047541

(51) Int. Cl. B08B 3/08; B08B 3/02; H01L 21/00

(52) U.S. Cl. 134/2; 134/93

(57) ABSTRACT

A cleaning apparatus for a semiconductor device that can include a cleaning tank and a plurality of anodic metals attached to an inner surface thereof and serving as sacrificial anodes during a cleaning sequence using a cleaning liquid.

The present application claims priority under 35 U.S.C. 119 and 35 U.S.C. 365 to Korean Patent Application No. 10-2007-0047541 (filed on May 16, 2007), which is hereby incorporated by reference in its entirety.

### BACKGROUND

Aspects of semiconductor technology have focused on manufacturing semiconductor devices having a high degree of integration, i.e., ultra-miniaturized. During the manufacturing process, wet etching was once widely used in a patterning process, but has been gradually replaced by dry etching technology using plasma. Dry etching technology using plasma allows reaction materials generated in plasma to chemically react with etching objects on the surface of a wafer to perform an etching operation. Since plasma dry etching technology makes fine patterning possible and has an anisotropic etching characteristic, it can improve the resolution of an etch model. For example, when plasma dry etching technology is used, generation of undercutting that the lower portion of a mask is etched can be suppressed. However, plasma dry etching technology has a limitation that a semiconductor device may be damaged by plasma.

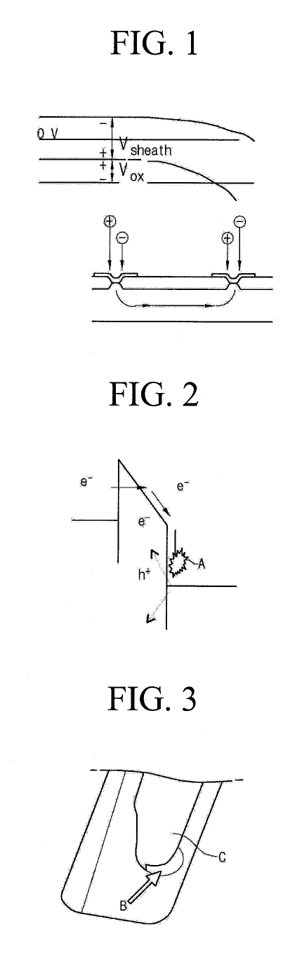

Example FIG. 1 illustrates a local potential difference generated in a semiconductor device by non-uniform plasma. Example FIG. 2 illustrates a tunneling phenomenon generated in a semiconductor device by a local potential difference. Example FIG. 3 illustrates a corroded shape of a metal interconnection.

When a reaction gas is injected into an etching chamber and a voltage is applied to a coil, an electromagnetic field is formed and plasma is formed by the electromagnetic field. Non-uniform plasma may be generated by the state of the electromagnetic field, a difference in the density of the reaction gas, and an ionization condition. A local potential difference may be generated by non-uniform ions.

As illustrated in example FIG. 1, potential Vₛₕₑₐₜₕ of an ion layer and potential Vₒₓ of an etch layer are not maintained constant but fluctuates unstably. Under this state, as illustrated in example FIG. 2, electron (e⁻)-hole (h⁺) pair may be induced at allowance prohibition band A due to a Fowler-Nordheim (FN) tunneling phenomenon to damage a gate oxide layer. Also, an ultra violet ray, a visible ray, and an infrared ray over a wide wavelength band of 150-800 nm generated inside the plasma may be delivered to the semiconductor device to generate undesired charged particles. In this case, damage of the semiconductor device may result. Also, a portion of a metal interconnection may be exposed due to line-end-shortening and misalignment generated when the metal interconnection is formed.

The semiconductor device passes through a cleaning process after an etching process and a deposition process may be performed. In a situation where the semiconductor device is damaged using the above-described factors, the damaged portion may be exposed to an electrolyte such as pure water. When the damaged portion of the semiconductor device is exposed to the electrolyte, a corrosion phenomenon occurs to influence the reliability of the device. Particularly, in case of plasma damage, a corrosion phenomenon occurs more seriously.

As illustrated in example FIG. 3, the corroded shape of metal interconnection C exposed by plasma damage is illustrated. A void is formed at the corroded portion. As described above, when a corrosion phenomenon occurs at the damaged portion of a semiconductor device, current flow may be blocked or is slow, so that the function of the semiconductor device is indispensably decreased.

### SUMMARY

Embodiments relate to a cleaning apparatus of a semiconductor device prevents metal corrosion during performing of the cleaning process.

Embodiments relate to a cleaning apparatus of a semiconductor device that can include at least one of the following: a cleaning tank receiving the semiconductor device and a cleaning liquid; and a plurality of anodic metals attached inside the cleaning tank to serve as sacrificial anodes, having a plate shape, and attached on one or more surfaces of the cleaning tank.

### DRAWINGS

Example FIG. 1 illustrates a local potential difference generated in a semiconductor device by non-uniform plasma.

Example FIG. 2 illustrates a tunneling phenomenon generated in a semiconductor device by a local potential difference.

Example FIG. 3 illustrates the corroded shape of a metal interconnection.

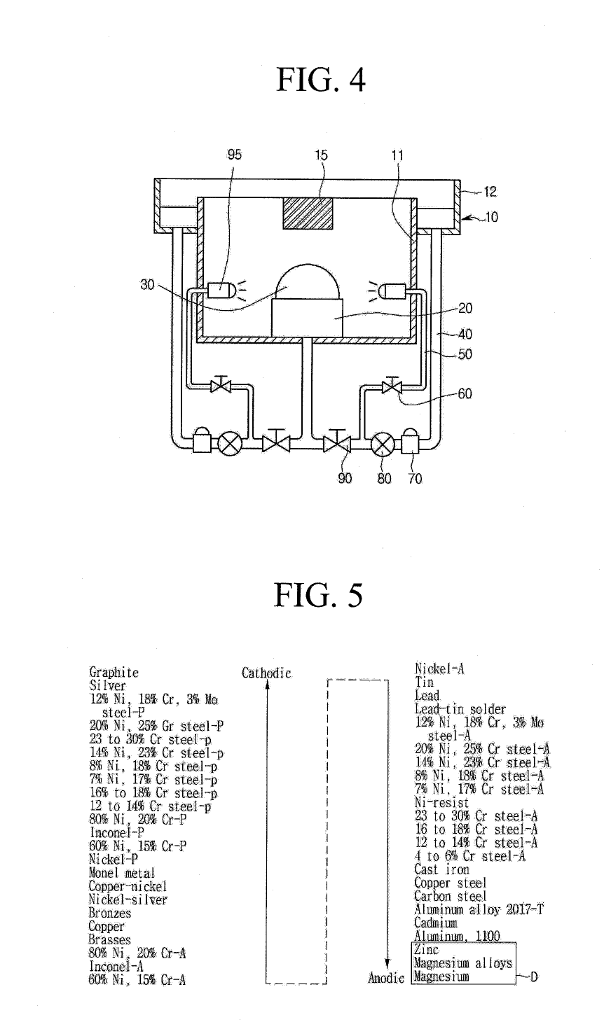

Example FIG. 4 illustrates a cleaning apparatus of a semiconductor device, in accordance with embodiments.

Example FIG. 5 illustrates a table showing galvanic series of metals and alloys.

### DESCRIPTION

A cleaning apparatus of a semiconductor device and a cleaning method of a semiconductor device according to an embodiment will be described in detail with reference to the accompanying drawings. The cleaning apparatus of the semiconductor device is a cleaning apparatus used for a metal interconnection process.

As illustrated in example FIG. 4, a cleaning apparatus of a semiconductor device in accordance with embodiments can include cleaning tank 10, boat 20, first circulation line 40, pump 70, filter 80, first valve 90, second circulation line 50, second valve 60, nozzle 95 and anodic metal 15. A semiconductor device in a wafer state is received in the boat 20.

Cleaning tank 10 can include an annular space sized to accommodate a cleaning liquid such as pure water and chemicals. Cleaning tank 10 can include first or inner tank 11 which receives boat 20 fixed therein, and second or outer tank 12 sized to receive first tank 11 at least at an upper portion thereof. Anodic metal 15 is attached on the upper surface of first tank 11 to serve as a sacrificial anode and prevent metal structures of the semiconductor device exposed to the cleaning liquid from being corroded during a generation process. For example, a tungsten plug of a semiconductor device may be exposed to the outside by line-end-shortening, misalignment, and plasma damage generated during interconnection forming. In this case, the corrosion of the metal structure can be prevented.

First circulation line 40 connects first tank 11 to second tank 12 to allow the cleaning liquid to flow therein. Pump 70, filter 80 and first valve 90 are connected to first circulation line 40. Nozzles 95 are connected to both sides of first tank 11 directed towards both sides of boat 30 with a constant interval, respectively. Each nozzle 95 is connected to a portion of the first circulation line 40 at a position between filter 80 and first valve 90 through second circulation line 50. Second valve 60 is connected to second circulation line 50.

During operation, when semiconductor device 30 in a wafer state is received on and/or over boat 20, first tank 11 is filled with a cleaning liquid such that anodic metal 15 extending through the top end of first tank 11 is immersed. When first tank 11 is filled with the cleaning liquid, first valve 90 connected to first circulation line 40 is closed. After that, the second valve 60 connected to second circulation line 50 is opened, and the cleaning liquid pumped by pump 70 is sprayed through nozzle 95 connected to second circulation line 50. When the cleaning liquid is sprayed towards boat 20 and anodic metal 15 through nozzle 95 for a predetermined time, second valve 60 connected to second circulation line 50 is closed and first valve 90 is opened. When pump 80 is in operation, the cleaning liquid circulates through first tank 11, first circulation line 40 and second tank 12 so that cleaning of semiconductor device 30 in a wafer state is performed.

“Metal oxidation reaction,” “hydrogen reduction reaction,” and “oxygen reduction reaction” simultaneously occur on and/or over the metal surface of semiconductor device 30 while the cleaning is performed. The speed of the oxidation reaction becomes equal to that of the reduction reaction on the whole, ions from the anode and the cathode flowing along the metal surface cancel each other, and a corrosion phenomenon occurs. However, another metal, i.e., a metal of an anodic component, having a lower potential than the potential of a metal forming the semiconductor device is connected to the metal forming the semiconductor device, the corrosion phenomenon that has occurred in the original metal occurs in the metal of the anodic component, so that the original metal can be protected. The metal of the anodic component is called a sacrificial anode. In accordance with embodiments, anodic metal 15 installed on cleaning tank 10 serves as a sacrificial anode and accommodate a corrosion phenomenon that may occur at semiconductor device 30. And thus, anodic metal 15 serves to protect semiconductor device 30 from the corrosion phenomenon. That is, a reduction reaction prevails, so that an oxidation reaction, which is a corrosion reaction, is suppressed on semiconductor device 30, and simultaneously, an oxidation reaction occurs on anodic metal 15.

In the above-described sacrificial anode method, a potential difference between a metal structure forming semiconductor device 30 and anodic metal 15 is an important factor. The galvanic series illustrated in example FIG. 5 illustrates a standard potential of metal and an alloy. Metals arranged in the upper portion have a cathodic component, and metals arranged in the lower portion have an anodic component. Anodic metal 15 can include one of metals D arranged last, that is, magnesium, a magnesium alloy, zinc, and a zinc alloy. Therefore, anodic metal 15 can prevent the corrosion of a metal having a greater standard potential than these metals. When anodic metal 15 is used, corrosion of metals such as Al, Cu, and W widely used for semiconductor device 30 can be prevented. Anodic metal 15 can be integrally formed or a plurality of anodic metals 15 can be provided regardless of the number of stackings of metal interconnections formed on semiconductor device 30. Also, anodic metals 15 can be attached on one or more surfaces of cleaning tank 10 depending on factors such as the location of nozzle 95, a spray pattern, and the flowing direction of the cleaning liquid. To widen a contact area with the cleaning liquid even more, anodic metal 15 can be manufactured in a plate shape, and can be attached on cleaning tank 10 using an adhesive member or through a process such as welding.

Therefore, in accordance with embodiments, since corrosion of the metal structure of the semiconductor device can be prevented during a cleaning process, the reliability of the semiconductor device can be improved. Also, in accordance with embodiments, even when the metal interconnection is exposed to the outside due to damage by plasma, line-end-shortening and misalignment, corrosion of the metal interconnection during the cleaning process can be prevented. Therefore, a separate compensation process does not need to be performed.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A cleaning apparatus for a semiconductor device, the apparatus comprising:
a cleaning tank sized to receive the semiconductor device;
a plurality of anodic metals attached to at least one inner surface of the cleaning tank to serve as sacrificial anodes; and
a nozzle for spraying a cleaning fluid on the semiconductor device and the anodic metals.

2. The apparatus according to claim 1, wherein the anodic metals are integrally formed with the cleaning tank.

3. The apparatus according to claim 1, wherein the anodic metals comprise at least one of magnesium, a magnesium alloy, zinc and a zinc alloy.

4. The apparatus according to claim 1, wherein the cleaning tank comprises:
an inner tank sized to receive the semiconductor device; and
an outer tank surrounding the peripheral surface of the inner tank, wherein the outer tank is fluidically connected to the inner tank.

5. The apparatus according to claim 4, further comprising:
a first cleaning fluid circulation line connecting the inner tank to the outer tank to allow the cleaning liquid to flow therebetween; and
a second cleaning fluid circulation line connecting the inner tank to the first cleaning fluid circulation line, wherein the nozzle is connected to the second cleaning fluid circulation line.

6. The apparatus according to claim 5, further comprising:
a pump connected to the first cleaning fluid circulation line for pumping the cleaning fluid;
a filter connected to the first cleaning fluid circulation line;
a first valve connected to the first cleaning fluid circulation line; and
a second valve connected to the second cleaning fluid circulation line.

7. The apparatus according to claim 6, wherein the second cleaning fluid circulation line is connected to the first cleaning fluid circulation line at a position between the filter and the first valve.

8. The apparatus according to claim 6, wherein during operation, when the inner tank is filled with the cleaning liquid, the first valve is closed and the second valve is opened permitting the cleaning liquid pumped by the pump to be sprayed through nozzle.

9. The apparatus according to claim 6, wherein during operation, after the nozzle sprays the cleaning liquid on the semiconductor device and the anodic metal for a predetermined time, the second valve is closed and the first valve is opened.

10. A cleaning apparatus comprising:
a first tank sized to receive a semiconductor device having at least one metal interconnection;
a second tank fluidically connected to the first tank;
a sacrificial anode composed of a metal attached to an inner surface of the first tank;
a first cleaning fluid circulation line connecting the first tank to the second tank to allow a cleaning liquid to flow therebetween; and
a second cleaning fluid circulation line connecting the first tank to the first cleaning fluid circulation line;
a pump connected to the first cleaning fluid circulation line for pumping the cleaning fluid; and
a nozzle connected to the second cleaning fluid circulation line and extending through the first tank for spraying the cleaning fluid on the semiconductor device and the sacrificial anode during a cleaning sequence.

11. The apparatus of claim 10, wherein the anodic metals comprise at least one of magnesium, a magnesium alloy, zinc and a zinc alloy.

12. The apparatus of claim 10, further comprising:
a filter connected to the first cleaning fluid circulation line;
a first valve connected to the first cleaning fluid circulation line; and
a second valve connected to the second cleaning fluid circulation line.

13. The apparatus of claim 12, wherein the second cleaning fluid circulation line is connected to the first cleaning fluid circulation line at a position between the filter and the first valve.

14. A method of cleaning a semiconductor device comprising:
providing a cleaning tank having at least one anodic metal serving as a sacrificial anode attached to at least one inner surface thereof and positioning the semiconductor device; and then
filling the cleaning tank with a cleaning liquid to immerse the anodic metal; and then
causing a metal oxidation reaction, a hydrogen reduction reaction and an oxygen reduction reaction on a metal surface of the semiconductor device.

15. The method of claim 14, wherein simultaneously causing the metal oxidation reaction, the hydrogen reduction reaction and the oxygen reduction reaction comprises spraying a cleaning fluid on the semiconductor device and the anodic metals.

16. The method of claim 10, wherein the anodic metal comprises at least one of magnesium, a magnesium alloy, zinc and a zinc alloy.

17. The method of claim 10, wherein the anodic metal is integrally formed with the cleaning tank.

18. The method of claim 10, wherein providing the cleaning tank comprises providing a cleaning tank having a plurality of anodic metals attached thereto.

19. The method of claim 18, wherein the anodic metals are integrally formed with the cleaning tank.

20. The method of claim 19, wherein the anodic metal comprises at least one of magnesium, a magnesium alloy, zinc and a zinc alloy.
